(19) United States
(12) Patent Application Publication
(10) Pub. No.: US 2024/0332146 A1
(43) Pub. Date: Oct. 3, 2024

(54) INTEGRATED CIRCUIT (IC) PACKAGE EMPLOYING METAL POSTS THERMALLY COUPLING A DIE TO AN INTERPOSER SUBSTRATE FOR DISSIPATING THERMAL ENERGY OF THE DIE, AND RELATED FABRICATION METHODS

(71) Applicant: QUALCOMM Incorporated, San Diego, CA (US)

(72) Inventors: Joan Rey Villarba Buot, Escondido, CA (US); Hong Bok We, San Diego, CA (US); Zhijie Wang, San Diego, CA (US); Sang-Jae Lee, San Diego, CA (US)

(21) Appl. No.: 18/193,295

(22) Filed: Mar. 30, 2023

(51) Int. Cl. H01L 23/498; H01L 21/48; H01L 23/00; H01L 23/42; H01L 23/538

(52) U.S. Cl. CPC H01L 23/49811; H01L 21/4857; H01L 23/42; H01L 23/49822; H01L 23/49833; H01L 23/5383; H01L 24/83; H01L 24/16; H01L 24/32; H01L 24/73; H01L 24/81; H01L 2224/16227; H01L 2224/32225; H01L 2224/73204; H01L 2224/81; H01L 2224/83

(57) ABSTRACT

Integrated circuit (IC) package employing metal posts thermally coupling a die to an interposer substrate for dissipating thermal energy of the die are disclosed. In one aspect, the IC package includes a metal post(s) thermally coupled to the die. The metal post(s) is attached to metal interconnect(s) (e.g., metal trace, metal pad, metal line, metal plate) in the interposer substrate. In this manner, as thermal energy is generated in the die, this thermal energy dissipates through the metal post(s) and through the coupled metal interconnect(s) into the interposer substrate. Thus, metal interconnects, which are an available feature in an interposer substrate fabrication process, are deployed to form the foundation upon which metal posts are fabricated and thermally coupled to the die to provide heat dissipation for the die in the IC package.

### BACKGROUND

### I. Field of the Disclosure

The field of the disclosure relates to integrated circuit (IC) packages, and more particularly to design and manufacture of an IC package to dissipate thermal energy away from a semiconductor die(s) in the IC package.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include metal interconnects (e.g., metal traces, metal lines) with vias coupling the metal interconnects together between adjacent metallization layers to provide electrical interfaces between the die(s). The die(s) is electrically interfaced to metal interconnects exposed in a top or outer metallization layer of the package substrate to electrically couple the die(s) to the metal interconnects of the package substrate. For example, the package substrate may include a laminate substrate or an embedded trace substrate (ETS) layer adjacent to and electrically coupled to a die to provide signal routing paths to the die. Metal interconnects in the outer metallization layer of the package substrate are coupled to other metal interconnects in other, lower metallization layers in the package substrate to provide signal routing paths to a coupled die.

Some IC packages are known as “hybrid” IC packages, which include multiple die packages with respective dies for different purposes or applications. For example, a hybrid IC package may be an application die, such as a communications modem or processor (including a system). The hybrid IC package could also include, for example, one or more memory dies to provide memory to support data storage and access by the application die. Multiple dies could be disposed in a single die layer and disposed adjacent to each other in a horizontal direction on a package substrate in the IC package. The multiple dies could also be provided in their own respective die packages that are stacked on top of each other in a three-dimensional (3D) arrangement as an overall 3DIC package. A die in a die layer is typically encased in an epoxy molding compound (EMC) to protect the die. 3DIC packages may be desired to reduce the cross-sectional area of the package. In a 3DIC package, a first, bottom die directly supported on a package substrate is electrically coupled through die interconnects to metallization layers of the package substrate to provide signal routing paths for the die in the package substrate. Other stacked dies that are not directly adjacent to the package substrate in the 3DIC package can be electrically coupled to the package substrate by wire bonds and/or intermediate interposers to provide die-to-die (D2D) connections between the multiple stacked dies. Beside protecting the die, the EMC provides some thermal dissipation of thermal energy generated by the first bottom die.

Today's dies in an IC package are increasing in functionality and in operational speeds. As the functionality/speed of a die increases, thermal energy generated within the die typically increases and can exceed the thermal dissipation capacity of the IC package. An increase in the functionality or speed of a die leads to the need to dissipate the thermal energy generated within the die. Efficient dissipation of thermal energy can be particularly important in 3DIC packages that include multiple stacked dies that each generate heat.

### SUMMARY

Aspects disclosed in the detailed description include an integrated circuit (IC) package employing metal posts thermally coupling a semiconductor die (“die”) to an interposer substrate for dissipating thermal energy in the die. Related fabrication methods are also disclosed. The IC package includes a die layer that includes a die coupled to a package substrate to provide signal routing paths to the die. As an example, to facilitate additional dies being stacked in the IC package as a three-dimensional (3D) IC (3DIC) package, the IC package also includes an interposer substrate adjacent to the die. The interposer substrate supports providing additional signal routing paths to the package substrate for external connections and/or die-to-die (D2D) connections. In an exemplary aspect, the IC package also includes a metal post(s) thermally coupled to the die and a metal interconnect(s) (e.g., metal trace, metal pad, metal line, metal plate) in the interposer substrate. In this manner, as thermal energy is generated in the die, this thermal energy dissipates from the die through the metal post(s) and through the coupled metal interconnect(s) into the interposer substrate. Thus, metal interconnects, which are an available feature in an interposer substrate fabrication process, are deployed to form the foundation upon which metal posts are fabricated and thermally coupled to the die to provide heat dissipation for the die in the IC package.

In this regard, in one exemplary aspect, an IC package is provided. The IC package comprises a package substrate and an interposer substrate extending in a first direction. The interposer substrate extending in a first direction comprises a first metal layer. The first metal layer comprises one or more first metal interconnects. The IC package further comprises a first die coupled to the package substrate. The first die is disposed between the package substrate and the interposer substrate. The IC package further comprises at least one metal post coupled to a first metal interconnect of the one or more first metal interconnects in the interposer substrate, and is adjacent and thermally coupled to the first die.

In another aspect, a method of fabricating an IC package is provided. The method comprises providing a package substrate. The method also comprises providing an interposer substrate extending in a first direction, the interposer substrate comprising a first metal layer, the first metal layer comprising one or more first metal interconnects. The method also comprises providing at least one metal post, each connected to a first metal interconnect of the one or more first metal interconnects. The method also comprises disposing a first die between the package substrate and the interposer substrate and coupling the first die to the package substrate. The method also comprises thermally coupling the first die to at least one metal post adjacent to the first die.

### BRIEF DESCRIPTION OF THE DRAWINGS

FIG. 1A is a side view of an integrated circuit (IC) package that includes at least one metal post thermally coupling a first die in a first die layer of the IC package to an interposer substrate adjacent to the die for dissipating thermal energy of the first die;

FIG. 1B is a close-up side view of the IC package in FIG. 1A that shows the interposer substrate thermally coupled to the first die through metal posts;

FIG. 1C is a bottom view of the interposer substrate in the IC package in FIG. 1A illustrating the metal posts extending in the vertical direction (Z-axis direction) between the first die layer and the interposer substrate;

FIG. 1D is a side view of an IC package that includes metal posts thermally coupling a first die in a first die layer of the IC package to an interposer substrate adjacent to the die for dissipating thermal energy of the first die wherein the interposer substrate does not contain thermal vias;

FIG. 2 is a flowchart illustrating an exemplary fabrication process of fabricating an IC package that includes an interposer substrate thermally coupled to the first die through the metal posts for dissipating thermal energy in the first die, including the IC package in FIGS. 1A-1C;

FIGS. 3A and 3B is a flowchart illustrating another exemplary fabrication process of fabricating the interposer substrate that includes metal posts built on a first metal plate in the interposer substrate;

FIGS. 4A-4F are exemplary fabrication stages during fabrication of the interposer substrate according to the fabrication process in FIGS. 3A and 3B;

FIGS. 5A and 5B is a flowchart illustrating another exemplary fabrication process of fabricating the interposer substrate that includes metal posts built on a first metal plate in the interposer substrate and a second metal plate thermally coupled to the first metal plate through thermal vias;

FIGS. 6A-6F are exemplary fabrication stages during fabrication of the interposer substrate according to the fabrication process in FIGS. 5A-5B;

FIGS. 7A-7C are a flowchart illustrating an exemplary assembly process of assembling an IC package employing metal posts thermally coupling a first die to an interposer substrate for dissipating thermal energy of the first die;

FIGS. 8A-8E are exemplary assembly stages during the assembly process of the IC package in FIGS. 7A-7C;

FIG. 9 is a block diagram of an exemplary wireless communications device that includes radio-frequency (RF) components deployed in an IC package employing at least one metal post thermally coupling a first die to an interposer substrate for dissipating thermal energy of the first die, including, but not limited to, the IC package in FIG. 1A-1D and FIGS. 8A-8E, and according to the exemplary fabrication and assembly processes in FIGS. 3A-3B, 5A-5B, and 7A-7C; and

FIG. 10 is a block diagram of an exemplary processor-based system that can include components deployed in an IC package employing at least one metal post thermally coupling a first die to an interposer substrate for dissipating thermal energy of the first die, including, but not limited to, the IC package in FIG. 1A-1D and FIGS. 8A-8E, and according to the exemplary fabrication and assembly processes in FIGS. 3A-3B, 5A-5B, and 7A-7C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include an integrated circuit (IC) package employing metal posts thermally coupling a semiconductor die (“die”) to an interposer substrate for dissipating thermal energy in the die. Related fabrication methods are also disclosed. The IC package includes a die layer that includes a die coupled to a package substrate to provide signal routing paths to the die. As an example, to facilitate additional dies being stacked in the IC package as a three-dimensional (3D) IC (3DIC) package, the IC package also includes an interposer substrate adjacent to the die. The interposer substrate supports providing additional signal routing paths to the package substrate for external connections and/or die-to-die (D2D) connections. In an exemplary aspect, the IC package also includes a metal post(s) thermally coupled to the die and a metal interconnect(s) (e.g., metal trace, metal pad, metal line, metal plate) in the interposer substrate. In this manner, as thermal energy is generated in the die, this thermal energy dissipates through the metal post(s) and through the coupled metal interconnect(s) into the interposer substrate. Thus, metal interconnects, which are an available feature in an interposer substrate fabrication process, are deployed to form the foundation upon which metal posts are fabricated and thermally coupled to the die to provide heat dissipation for the die in the IC package.

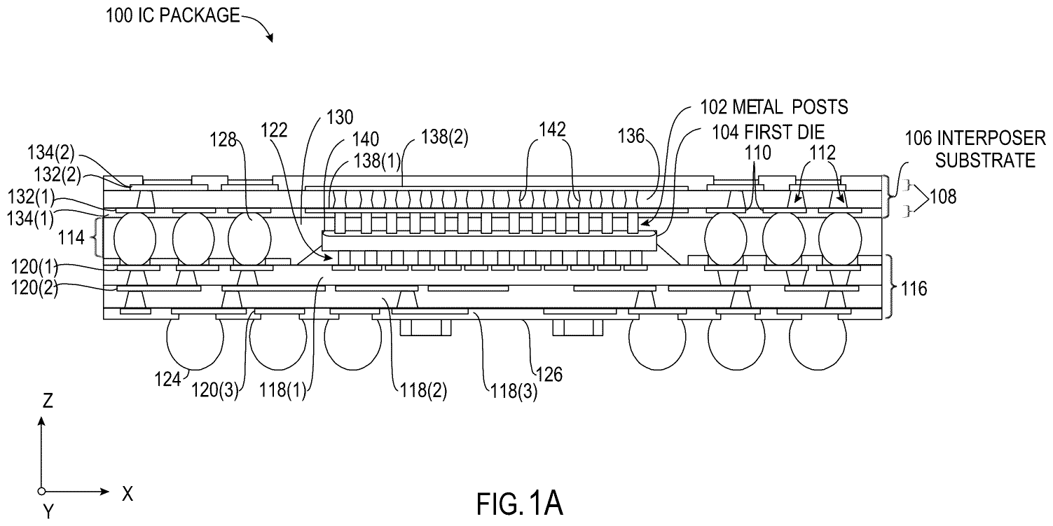

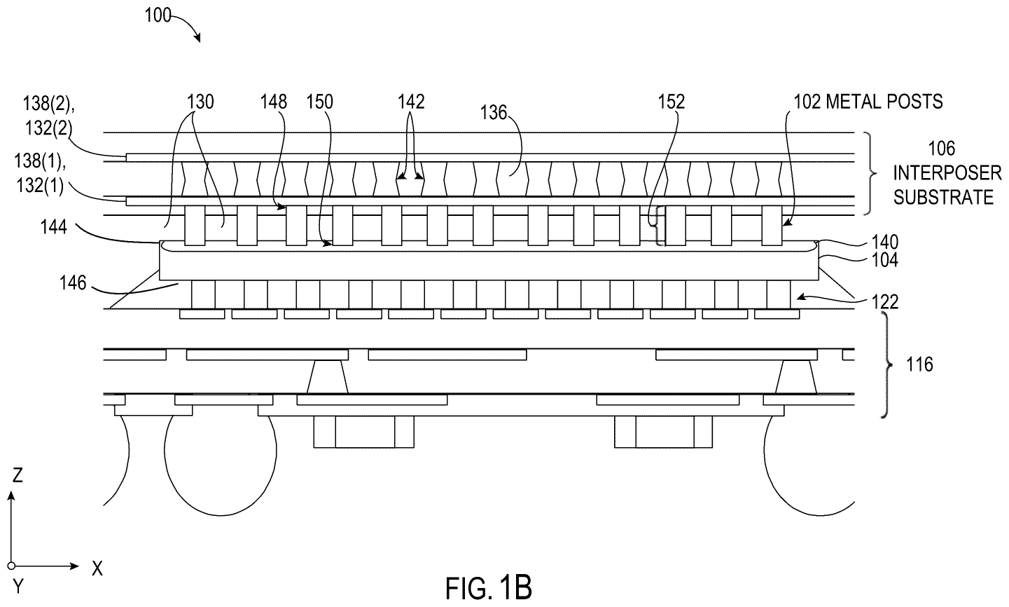

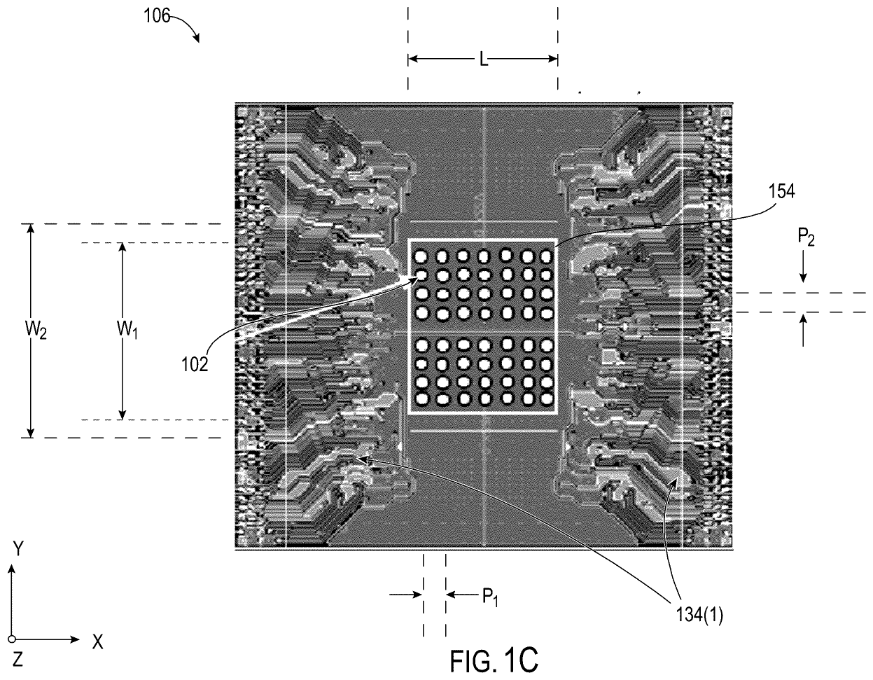

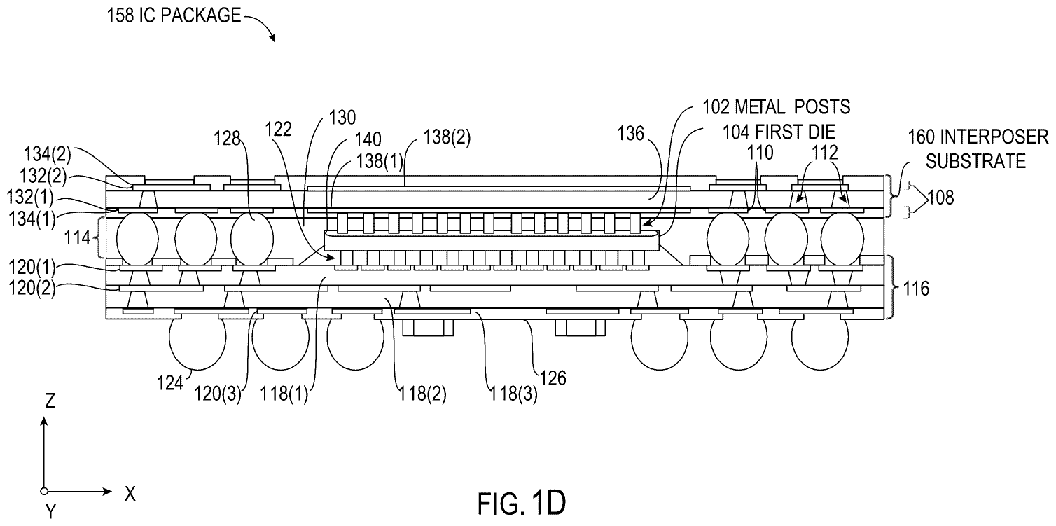

In this regard, FIG. 1A is a side view of an integrated circuit (IC) package 100 that includes metal posts 102 thermally coupled to a first die 104 in a first die layer 114 of the IC package 100 to an interposer substrate 106 adjacent to the first die 104 for dissipating thermal energy of the first die. By “the interposer substrate 106 adjacent to the first die 104”, it is meant that the interposer substrate 106 and first die 104 are spatially next to each other or beside each other with some intervening space. Metal posts 102 are not limited to a particular number and may include at least one metal post. As discussed in more detail below, as thermal energy is generated in the first die 104, this thermal energy dissipates through the metal posts 104 and through the interposer substrate 106. The interposer substrate 106 extends in a first, horizontal direction(s) (X- and/or Y-axis direction(s)). The interposer substrate 106 includes metallization layers 108 each with routing metal interconnects 110 (e.g., metal traces, metal lines, metal pads) for providing signal routing through the interposer substrate 106. Metallization layers 108 includes a metal layer and an insulating layer. Signal routing between non-directly adjacent metallization layers 108 in the interposer substrate 106 are provided by vias 112, which are vertical metal interconnects extending in the second, vertical direction (Z-axis direction). The interposer substrate 106 is coupled to the first die layer 114 that includes the first die 104 coupled to a package substrate 116.

For example, the package substrate 116 could be a laminate substrate or an embedded trace substrate (ETS). The package substrate 116 includes a plurality of metallization layers 118(1)-118(3) in this example that each include respective metal interconnects 120(1)-120(3) (e.g., metal traces, metal lines, metal pads) for providing signal routing to the first die 104 in the first die layer 114 coupled to the package substrate 116. The metallization layers 118(1)-118(3) are parallel to each other and directly adjacent to each other, and extend in a first, horizontal direction(s) (X- and/or Y-axis direction(s)). The first die 104 is disposed between package substrate 116 and interposer substrate 106 in a first, horizontal direction(s) (X- and/or Y-axis direction(s)) and is electrically coupled to the package substrate 116 by die interconnects 122 coupled to the metal interconnects 120(1) in the first, upper metallization layer 118(1) of the package substrate 116. The package substrate 116 is configured to provide signal routing paths through the coupling of metal interconnects 120(1)-120(3) in its respective metallization layers 118(1)-118(3) between the first die 104 and external interconnects 124 (e.g., solder balls, ball grid array (BGA) interconnects, etc.) for the IC package 100.

As shown in FIG. 1A, external interconnects 124 are on the land side 126 of the package substrate 116. The IC package 100 in FIGS. 1A-1C is arranged such that there is also electrical coupling provided between the interposer substrate 106 and the package substrate 116. This is so that, for example, signal routing can be provided between a second die (not shown) coupled to the interposer substrate 106 and the package substrate 116 and/or the external interconnects 124 with the IC package 100. In this regard, vertical interconnects 128 (e.g., metal posts, metal pillars, metal balls) are disposed in the lower, first die layer 114 and surrounded by a molding compound 130 and coupled to the metal vias 112 in the interposer substrate 106 and the package substrate 116 to provide an electrical connection between the interposer substrate 106 and the package substrate 116.

With continuing reference to FIG. 1A, and as discussed in more detail below, metallization layer 108 of interposer substrate 106 includes a first metal layer 132(1) and a second metal layer 132(2). First routing metal interconnects 134(1) (e.g., metal traces, metal lines, metal pads) provided by certain routing metal interconnects 110 are formed in the first metal layer 132(1). Second routing metal interconnects 134(2) (e.g., metal traces, metal lines, metal pads) provided by certain routing metal interconnects 110 are formed in the second metal layer 132(2). The first routing metal interconnects 134(1) and the second routing metal interconnects 134(2) are parallel to each other and on opposite sides of insulating layer 136 within the metallization layer 108, and extend in a first, horizontal direction(s) (X- and/or Y-axis direction(s)). The first and second routing metal interconnects 134(1), 134(2) can be connected to each other with vias 112 for providing signal routing paths within the interposer substrate 106. One or more first metal interconnects 138(1) (e.g., metal traces, metal lines, metal plate) are formed in the first metal layer 132(1). Optionally, the first metal interconnects 138(1) may be formed as a metal plate during the fabrication of the interposer substrate 106 to provide more metal surface area to attract thermal energy from the first die 104. Also optionally, one or more second metal interconnects 138(2) (e.g., metal traces, metal lines, metal plate) may be included on the insulating layer 136. Insulating layer 136 may optionally include thermal vias 142 which thermally couple one or more first metal interconnects 138(1) with one or more second metal interconnects 138(2). Optionally, the second metal interconnects 138(2) may be formed as a metal plate during the fabrication of the interposer substrate 106. As thermal energy is generated in the first die 104, the metal posts 102 draw the thermal energy away from the first die 104 and conducts the thermal energy to first metal interconnects 138(2) through the thermal vias 142. Over time, the thermal energy in the first metal interconnects 138(1), 138(2) and thermal vias 142 radiate into the insulating layer 136 of the interposer substrate 106. The term “thermally coupled” as used herein means that thermal energy is drawn from a heat source to a heat sink or an intermediate conduit of thermal energy to a heat sink.

A thermal interface material 140 can optionally be coupled to the first die 104, between the first die 104 and the interposer substrate 106, to enhance the thermal coupling of the first die 104 to the metal posts 102 and thus the interposer substrate 106. Thermal interface material draws heat from a heat source. An example of thermal interface material includes ShinEtsu G-769EL thermal paste.

FIG. 1B is a close-up side view of the IC package 100 in FIG. 1A that shows the interposer substrate 106 thermally coupled to the first die 104 through metal posts 102. The first die 104 has a back side 144 and an active side 146. The back side 144 is the side of the first die 104 that is formed during the front-end-of-line (FEOL) process. The active side 146 is the side of the first die 104 that is formed during the back-end-of-line (BEOL) process. The active side 146 is electrically coupled to the package substrate 116 through die interconnects 122. As it is shown in FIG. 1B, the thermal interface material 140 is on the back side 144 of the first die 104.

As discussed above, metal posts 102 is provided in the interposer substrate 106 to provide thermal coupling between the first die 104 and the interposer substrate 106 for heat dissipation. The metal posts 102 has a first end 148 connected to one or more first metal interconnects 138(1) and each extends in a second, vertical direction (Z-axis direction) toward the first die 104. The metal posts 102 has a second end 150 that is adjacent to the first die 104 and thermally couples to the first die 104. Optionally, at least one of the second ends 150 of the metal posts 102 may terminate adjacent to the thermal interface material 140, may contact the thermal interface material 140, and/or may also contact the back side 144 of the first die 104. The length 152 of at the least one metal post 102 can be between thirty (30) micrometers (μm) and one hundred (100) μm, inclusively.

As illustrated in FIG. 1B, molding compound 130 is between the metal posts 102 and encompasses the top of the first die 104 between the interposer substrate 106 and the package substrate 116. The molding compound 130 insulates the metal posts 102 and other conductive components in the first die layer 114 and protects the first die 104 in the IC package 100.

Also, as illustrated in FIG. 1B, the first metal interconnects 138(1) and the second metal interconnects 138(2) in respective first and second metal layers 132(1), 132(2) of the interposer substrate 106 are parallel to each other in a first, horizontal direction (X- and/or Y-axis direction(s)) and are disposed on opposite sides of insulating layer 136. The first metal interconnects 138(1) and the second metal interconnects 138(2) are said to be coextensive since the area that they cover in the second, vertical direction (Z-axis direction) is the same. As such, when the first metal interconnects 138(1) are formed as a first metal plate and the second metal interconnects 138(2) are formed as a second metal plate, the first and second metal interconnects 138(1), 138(2) are coextensive and coupled through thermal vias 142.

FIG. 1C is a bottom view of the interposer substrate 106 in the IC package 100 in FIG. 1A with the metal posts 102 extending in the second, vertical direction (Z-axis direction). Footprint 154 of the first die 104 having a length L and a first width W1 in the X and Y directions is positioned in alignment with and encompasses the area (L×W1) of the metal posts 102 which are arranged in an array and electrically isolated from the first routing metal interconnects 134(1). In another embodiment, the metal posts 102 may extend further in the Y-direction to a second width W2 to define an area greater than footprint 154 and avoiding electrically coupling first routing metal interconnects 134(1). As the area of the metal posts 102 increases while the footprint 154 remains constant, more thermal energy will be dissipated from the first die 104 into the interposer substrate 106.

Continuing with reference to FIG. 1C, first pitch P1 is the distance (in the X-direction) between the center of one of the metal posts 102 to the center of its nearest neighboring metal post (in the X-direction). Second pitch P2 is the distance (in the Y-direction) between the center of one of the metal posts 102 to the center of its nearest neighboring metal post 102 (in the Y-direction). Pitches P1 and/or P2 between any neighboring metal post 102 may be between 100 μm and 200 μm, inclusively, as an example.

As an alternative embodiment to FIG. 1A, FIG. 1D is a side view of an IC package 158 that includes metal posts 102 thermally coupling a first die 104 in a first die layer 114 of the IC package 158 to an interposer substrate 160 adjacent to the first die 104 for dissipating thermal energy of the first die. By “the interposer substrate 160 adjacent to the first die 104”, it is meant that the interposer substrate 160 and first die 104 are spatially next to each other or beside each other with some intervening space. The interposer substrate 160 does not contain thermal vias. Common elements between the IC package 158 and elements of the IC package 100 in FIGS. 1A-1C are shown with common element numbers. As shown in FIG. 1D, the IC package 158 includes the first metal interconnects 138(1) and second metal interconnects 138(2) which do not connect to each other. Thermal energy generated in the first die 104 dissipates through the metal posts 102, into the first metal interconnects 138(1), and slowly radiates throughout interposer 106 including insulating layer 136. In this embodiment, because metal interconnects 138(1) in which the posts are coupled do not connect to metal interconnects 138(2) in the interposer substrate, that the heat is not dissipated directly through additional metal layers. This embodiment may be acceptable if the heat dissipation requirements can be met by heat dissipation provided by the coupling of the metal posts and a single metal layer for the IC package. The interposer substrate may be designed so that the metal posts are thermally coupled through a number of metal layers in the interposer substrate.

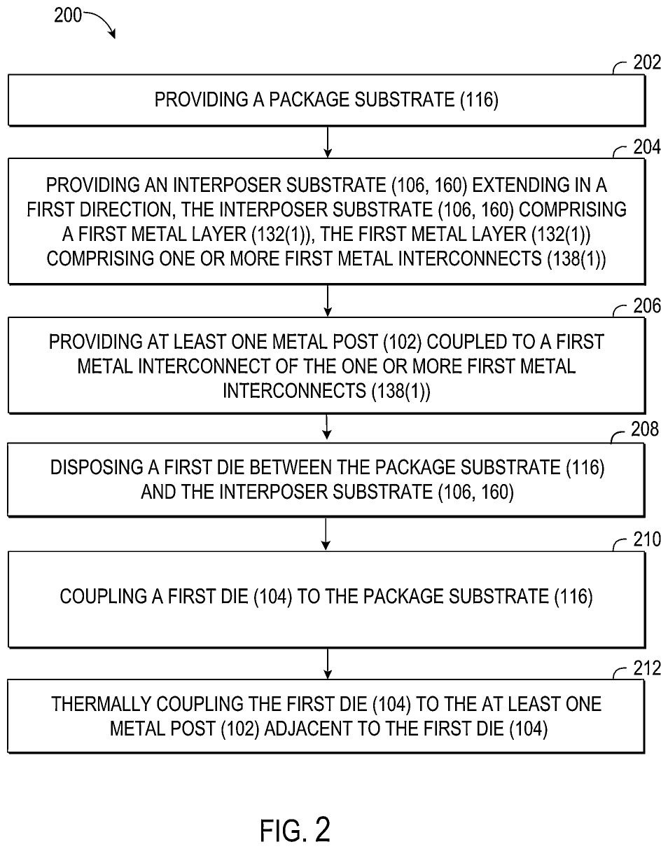

An interposer substrate that includes employing at least one metal post thermally coupled to a first die for dissipating thermal energy of the first die, including but not limited to the interposer substrates 106, 160 in the related IC packages 100, 158, respectively in FIGS. 1A-1D, can be fabricated in different fabrication processes. In this regard, FIG. 2 is a flowchart illustrating an exemplary fabrication process 200 of fabricating an IC package that includes an interposer substrate thermally coupled to the first die through the at least one metal post for dissipating thermal energy in the first die, including but not limited to the interposer substrates 106, 160 and related IC packages 100, 158 respectively in FIGS. 1A-1D as an example. The fabrication process 200 in FIG. 2 will be discussed in conjunction with the interposer substrate 106 and package substrate 116 in FIGS. 1A-1D as an example, but note that such is not limiting.

In this regard, a first exemplary step in the fabrication process 200 of FIG. 2 can include providing a package substrate 116 (block 202 in FIG. 2). A next step in the fabrication process 200 can include providing an interposer substrate 106, 160, extending in a first, horizontal direction in the X- and/or Y-axis directions, the interposer substrate 106 comprising a first metal layer 132(1), the first metal layer 132(1) comprising one or more first metal interconnects 138(1) (block 204 in FIG. 2). A next step in the fabrication process 200 can include providing metal posts 102 coupled to a first metal interconnect of the one or more first metal interconnects 138(1) (block 206 in FIG. 2). A next step in the fabrication process 200 can include disposing a first die 104 between the package substrate 116,160 and the interposer substrate 106 (block 208 in FIG. 2). A next step in the fabrication process 200 can include coupling a first die 104 to the package substrate 116 (block 210 in FIG. 2). A next step in fabrication process 200 can include thermally coupling the first die 104 to metal posts 102 adjacent to the first die 104 (block 212 in FIG. 2).

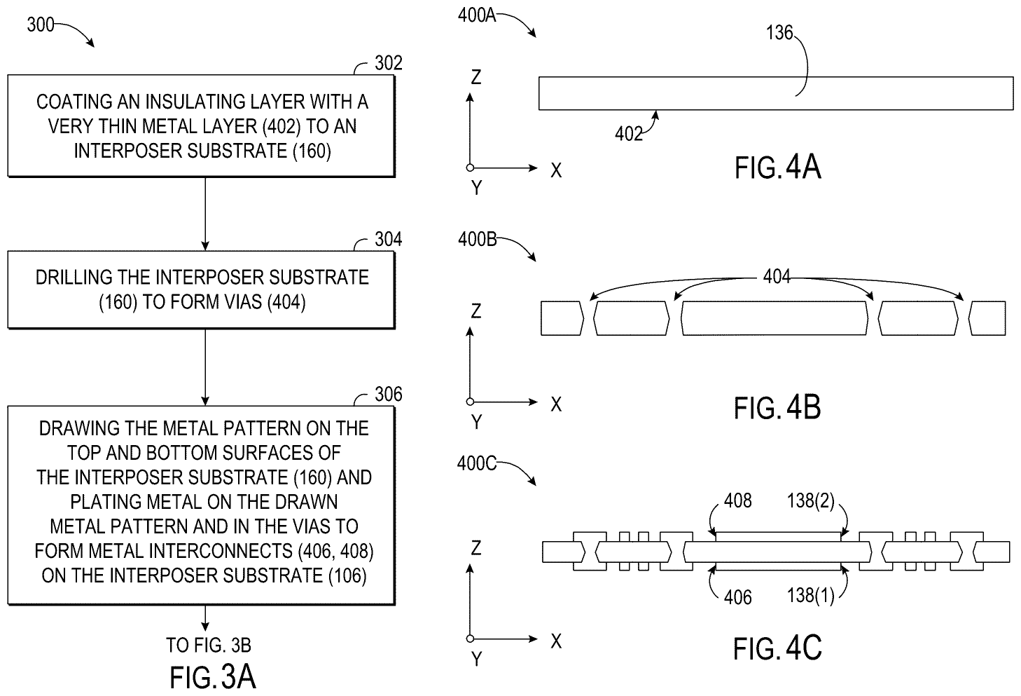

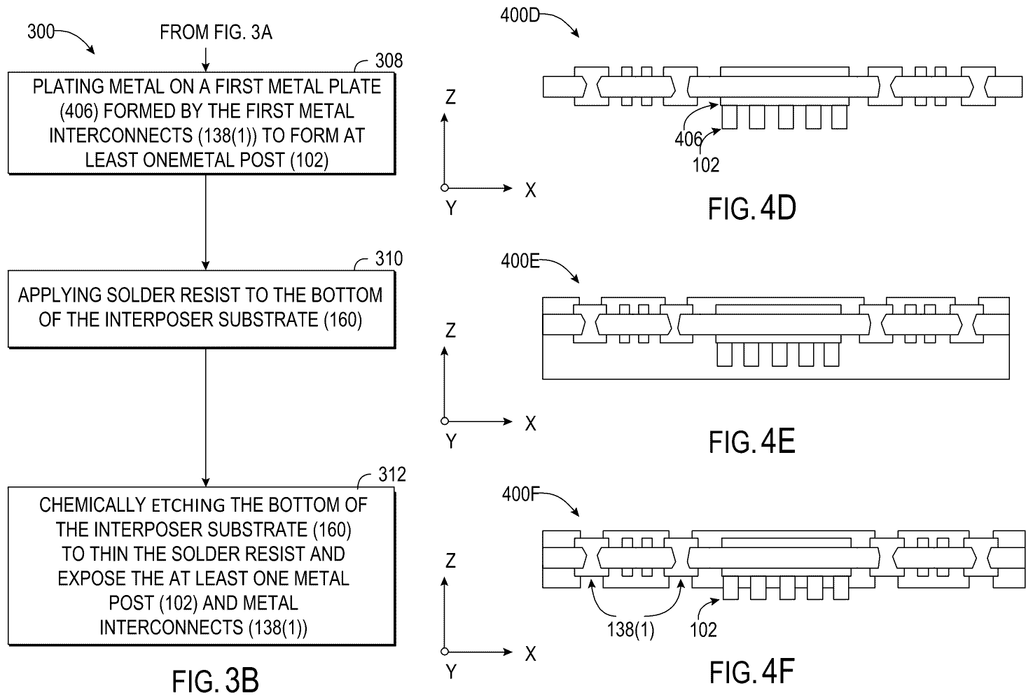

Other fabrication processes can also be employed to fabricate an interposer substrate with at least one metal post thermally coupling the interposer substrate with a first die, including but not limited to interposer substrates 106, 160 and related IC packages 100, 158 in FIGS. 1A, 1D, respectively. In this regard, FIGS. 3A and 3B is a flowchart illustrating another exemplary fabrication process 300 of fabricating an interposer substrate 160 that includes metal posts 102 built on a first metal plate in the interposer substrate, including but not limited to interposer substrate 160 and related IC package 158 in FIG. 1D. FIGS. 4A-4F are exemplary fabrication stages during fabrication of the interposer substrate 160 according to the fabrication process 300 in FIGS. 3A and 3B. The fabrication process 300 as shown in the fabrication stages 400A-400F in FIGS. 4A-4F are in reference to interposer substrate 160 and related IC package 158 in FIG. 1D, and thus will be discussed with reference to the interposer substrate 160 and IC package 158 in FIG. 1D.

In this regard, as shown at fabrication stage 400A in FIG. 4A, an exemplary step in the fabrication process 300 is to coat an insulating layer 136 with very thin metal layers 402 to form the beginnings of an interposer substrate 160 (block 302 in FIG. 3A). A next step in fabrication process 300 can include drilling the interposer substrate 160 to form vias 404 in the interposer substrate 160 (block 304 in FIG. 3A, stage 400B). A next step in fabrication process 300 can include drawing the metal pattern on the top and bottom surfaces of the interposer substrate 160 and plating metal on the drawn metal pattern and in the vias 404 to form first metal interconnects 138(1) and second metal interconnects 138(2) on the bottom and top of the interposer substrate 160, respectively (block 306 in FIG. 3A, stage 400C). The first metal interconnects 138(1) form a first metal plate 406 and the second metal interconnects 138(2) form a second metal plate 408. A next step in fabrication process 300 can include plating metal on the first metal plate 406 to form metal posts 102 (block 308 in FIG. 3B, stage 400D). As shown in FIG. 4D, a metal plate is defined as metal extending in both the first X- and Y-directions across metal posts 102 and having a thickness in the second, Z-direction. The first metal plate 406 has a thickness in the Z-direction in the range between 10 μm and 18 μm, inclusively, and the second metal plate 408 has a thickness in the Z-direction in the range between 10 μm and 18 μm, inclusively. A next step in fabrication process 300 can include applying solder resist to at least the bottom of the interposer substrate 160 (block 310 in FIG. 3B, stage 400E). A next step in fabrication process 300 can include chemically etching the bottom of the interposer substrate 160 to thin the solder resist and expose the metal posts 102 and expose metal interconnects, for example routing metal interconnects 110, which are used for routing signals through the interposer substrate 160 through metal interconnects 138(1) (block 312 in FIG. 3B, stage 400F). Fabrication process 300 described above is a 2-layer modified semi-additive process (MSAP). Similarly, other fabrication processes including embedded trace fabrication processes can be deployed to fabricate the interposer substrate 160.

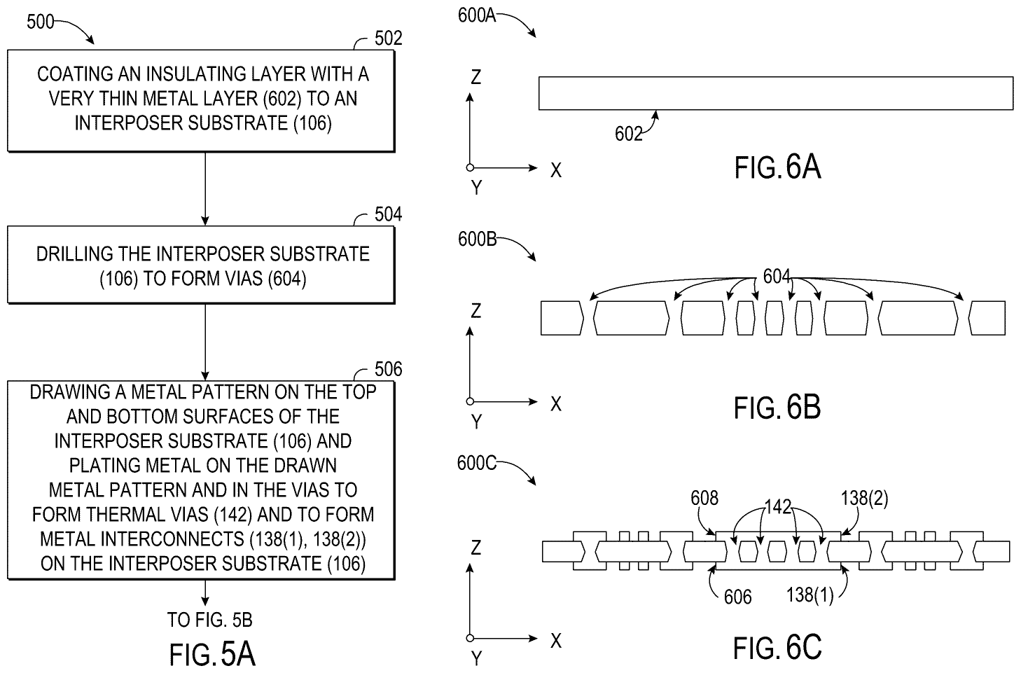

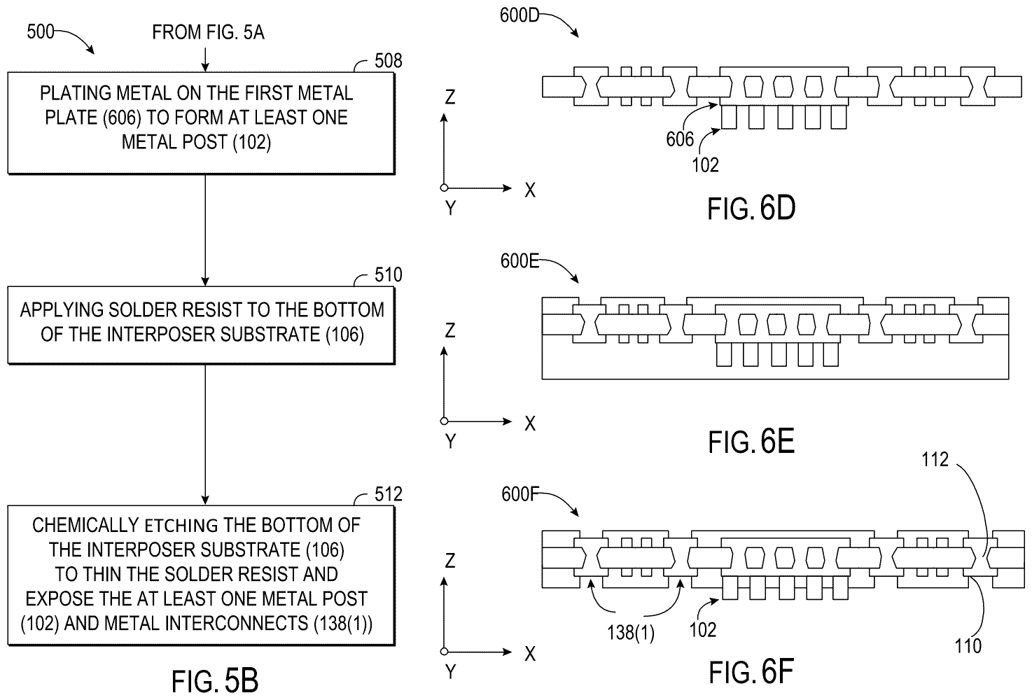

Other fabrication processes can also be employed to fabricate an interposer substrate with at least one metal post thermally coupling the interposer substrate with a first die, including but not limited to interposer substrate 106 and related IC packages 100 and 158 in FIG. 1A-1D. In this regard, FIGS. 5A and 5B are a flowchart illustrating another exemplary fabrication process 500 of fabricating an interposer substrate that includes at least one metal post built on a first metal plate in the interposer substrate and a second metal plate thermally coupled to the first metal plate through thermal vias, including but not limited to interposer substrate 106 and related IC package 100 in FIG. 1A. FIGS. 6A-6F are exemplary fabrication stages during fabrication of the interposer substrate 106 according to the fabrication process 500 in FIGS. 5A and 5B. The fabrication process 500 as shown in the fabrication stages 600A-600F in FIGS. 6A-6F are in reference to interposer substrate 106 and related IC package 100 in FIG. 1A, and thus will be discussed with reference to the interposer substrate 106 and IC package 100 in FIG. 1.

In this regard, as shown at fabrication stage 600A in FIG. 6A, an exemplary step in the fabrication process 500 is to coat an insulating layer 136 with very thin metal layers 602 to form the beginnings of an interposer substrate 106 (block 502 in FIG. 5A). A next step in fabrication process 500 can include drilling the interposer substrate 106 to form vias 604 in the interposer substrate 106 (block 504 in FIG. 5A, stage 600B). As also shown in the fabrication stage 600C in FIG. 6, next step in fabrication process 500 can include drawing the metal pattern on the top and bottom surfaces of the interposer substrate 106 and plating metal on the drawn metal pattern and in the vias 604 to form thermal vias 142 and to form first metal interconnects 138(1) and second metal interconnects 138(2) on the bottom and top of the interposer substrate 106, respectively (block 506 in FIG. 5A, stage 600C). First metal interconnects 138(1) form a first metal plate 606 and second metal interconnects 138(2) form a second metal plate 608. The first metal plate 606 has a thickness in the Z-direction in the range between 10 μm and 18 μm, inclusively, and the second metal plate 608 has a thickness in the Z-direction in the range between 10 μm and 18 μm, inclusively. As also shown in the fabrication stage 600D in FIG. 6, next step in fabrication process 500 can include plating metal on the first metal plate 606 to form metal posts 102 (block 508 in FIG. 5B, stage 600D). As also shown in the fabrication stage 600E in FIG. 6, next step in fabrication process 500 can include applying solder resist to at least the bottom of the interposer substrate 106 (block 510 in FIG. 3B, stage 600E). As also shown in the fabrication stage 600F in FIG. 6, next step in fabrication process 500 can include chemically etching the bottom of the interposer substrate 106 to thin the solder resist and expose the metal posts 102 and expose first metal interconnects 138(1), for example routing metal interconnects 110, which are used for routing signals through the interposer substrate through vias 112 (block 512 in FIG. 5B, stage 600F). Fabrication process 500 described above is a modified 2-layer modified semi-additive process (MSAP). Similarly, other fabrication processes including embedded trace fabrication processes can be deployed to fabricate the interposer substrate 106.

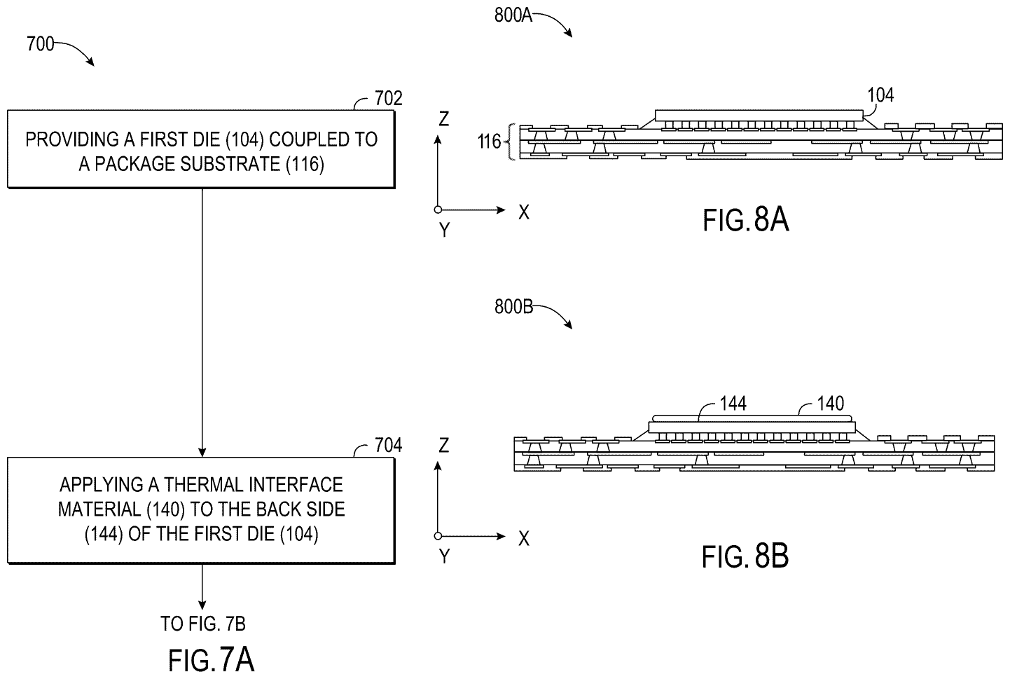

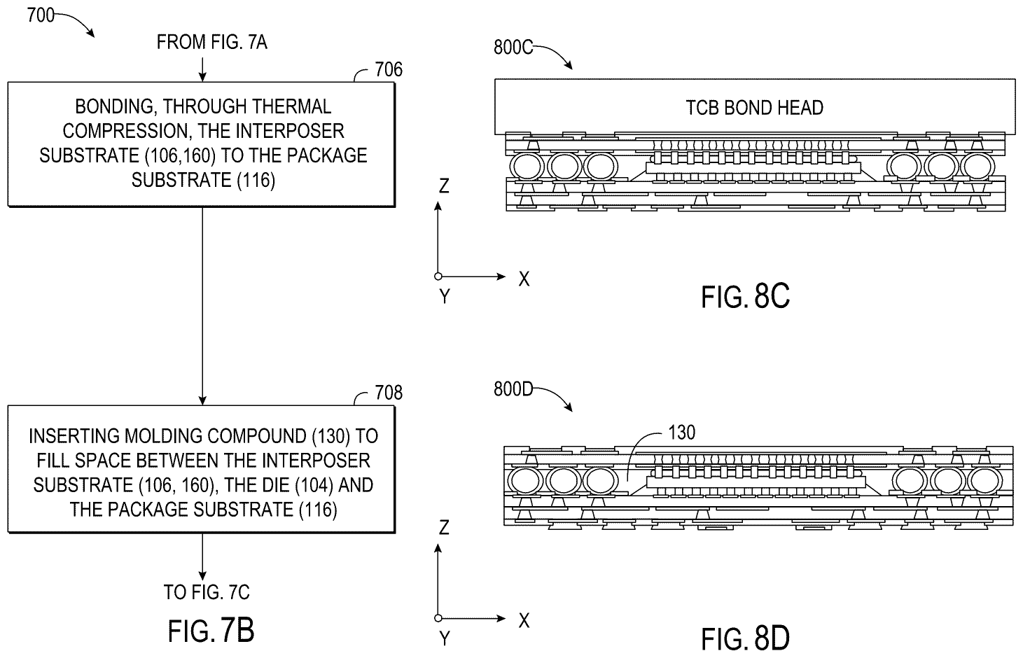

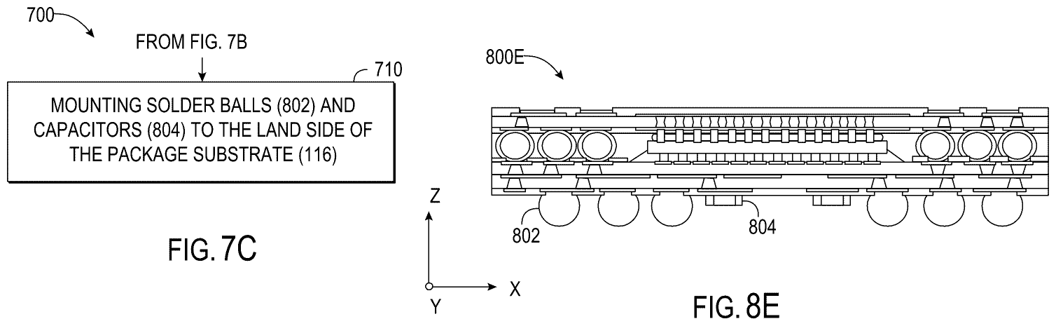

An IC package that includes employing at least one metal post thermally coupling a first die to an interposer substrate 106, 160 for dissipating thermal energy of the first die, including but not limited to IC package 100, 158, respectively, in FIGS. 1A-1D, can be assembled utilizing different assembly processes. In this regard, FIGS. 7A-7C are a flowchart illustrating an exemplary assembly process of assembling an IC package employing metal posts thermally coupling a first die to an interposer substrate 106, 160 for dissipating thermal energy of the first die, including but not limited to IC package 100 and IC package 158 in FIGS. 1A-1D as an example. The assembly process 700 in FIGS. 7A-7C will be discussed in conjunction with the interposer substrate 106, first die layer 114, and package substrate 116 in FIGS. 1A-1D, as an example.

In this regard, as shown at assembly stage 800A in FIG. 8A, an exemplary initial step in the assembly process 700 is to begin with providing a first die 104 coupled to a package substrate 116 (block 702 in FIG. 7A, stage 800A). As also shown in the fabrication stage 800B in FIG. 8, a next step in assembly process 700 can include applying a thermal interface material 140 to the back side 144 of the first die 104 (block 704 in FIG. 7A, stage 800B). The thermal interface material 140 may come in various forms and be applied in accordance with those forms. For example, thermal interface material 140 may be a thermal paste that is applied to the first die 104 by brushing the paste on the back side 144 of the first die 104 (also known as a dispense process). In another example, thermal interface material 140 may be in the form of a film which is adhesively attached to the back side 144 to the first die 104. As also shown in the fabrication stage 800C in FIG. 8, a next step in assembly process 700 can include bonding, through thermal compression, the interposer substrate 106 to the package substrate 116 (block 706 in FIG. 7B, stage 800C). As also shown in the fabrication stage 800D in FIG. 8, a next step in assembly process 700 can include inserting molding compound to fill space between the interposer substrate 106, the first die 104, and the package substrate 116 (block 708 in FIG. 7B, stage 800D). As also shown in the fabrication stage 800E in FIG. 8, a next step in assembly process 700 can optionally include external interconnects, such as mounting solder balls 802, and mounting external capacitors 804 to the land side of the package substrate 116 (block 710 in FIG. 7C, stage 800E).

An object being “adjacent” as discussed in this application relates to an object being beside or next to another object with intervening space between them. Adjacent objects may not be physically coupled to each other. Directly adjacent objects means that such objects are directly beside or next to each other without another of the objects being intervening or disposed between the directly adjacent objections. Non-directly adjacent objects means that such objects are not directly beside or next to each other without another of the objects being intervening or disposed between the non-directly adjacent objects.

The IC package employing metal posts thermally coupling a die to an interposer substrate for dissipating thermal energy of the die, including but not limited to the IC package 100 and IC package 158 and interposer substrate 106 and interposer substrate 160 in FIGS. 1A-1D, 4A-4F, and 6A-6F, and according to the exemplary fabrication and assembly processes in FIG. 2, FIGS. 3A-3B, 5A-5B, and 7A-7C, and according to aspects disclosed herein may be provided in or integrated into any processor-based device or wireless device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, and avionics systems.

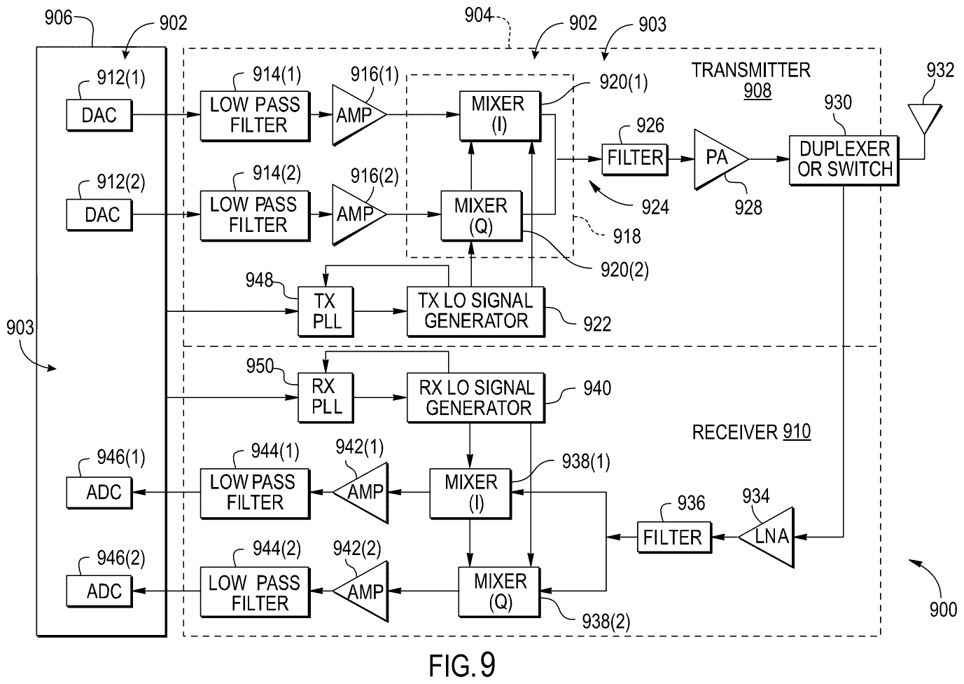

In this regard, FIG. 9 illustrates an exemplary wireless communications device 900 that includes radio frequency (RF) components formed from one or more ICs 902, wherein any of the ICs 902 can include an IC package employing metal posts thermally coupling a die to an interposer substrate for dissipating thermal energy of the die, and according to any aspects disclosed herein. The wireless communications device 900 may include or be provided in any of the above referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage in receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals from a TX LO signal generator 922 through mixers 920(1), 920(2) to provide an upconverted signal 924. A filter 926 filters the upconverted signal 924 to remove undesired signals caused by the frequency upconversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

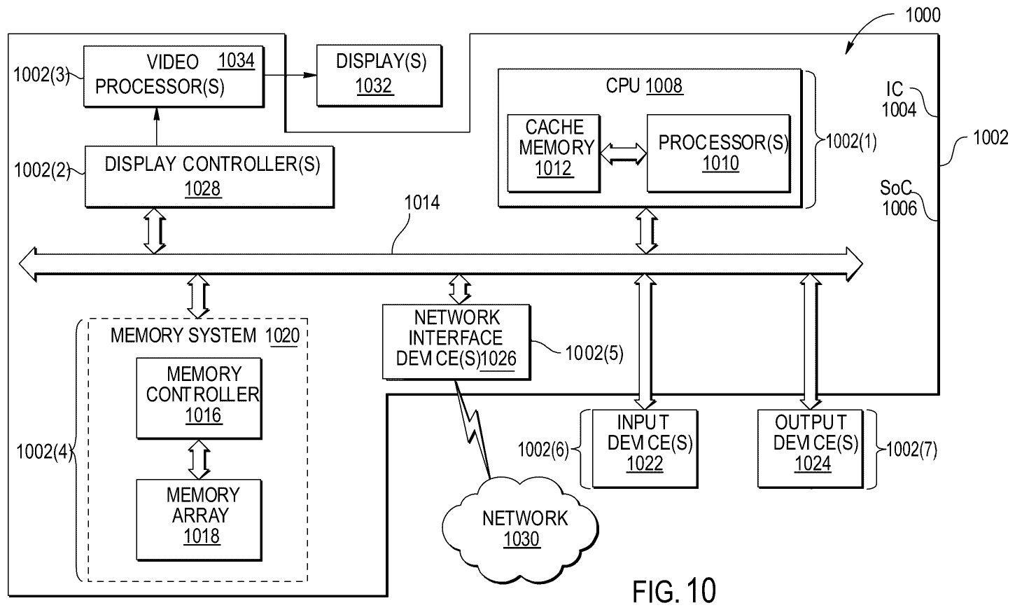

Regarding exemplary processor-based devices, FIG. 10 illustrates an example of a processor-based system 1000 that includes circuits that can be provided in IC packages 1002, 1002(1)-1002(7). Any of the IC packages 1002, 1002(1)-1002(7) can include metal posts thermally coupling a die to an interposer substrate for dissipating thermal energy in the die, including but not limited to interposer substrates 106, 160 in FIGS. 1A-1D, 4A-4F, and 6A-6F, the related IC packages 100, 158 in FIGS. 1A-1D, according to the exemplary fabrication and assembly processes in FIGS. 2, 3A-3B, and 5A-5B, and according to any aspects disclosed herein. In this example, the processor-based system 1000 may be formed as an IC 1004 in an IC package 1002 and as a system-on-a-chip (SoC) 1006. The processor-based system 1000 includes a central processing unit (CPU) 1008 that includes one or more processors 1010, which may also be referred to as CPU cores or processor cores. The CPU 1008 may have cache memory 1012 coupled to the CPU 1008 for rapid access to temporarily stored data. The CPU 1008 is coupled to a system bus 1014 and can intercouple master and slave devices included in the processor-based system 1000. As is well known, the CPU 1008 communicates with these other devices by exchanging address, control, and data information over the system bus 1014. For example, the CPU 1008 can communicate bus transaction requests to a memory controller 1016, as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that can be in a separate IC package 1002(4) and that includes the memory controller 1016 and a memory array(s) 1018, one or more input devices 1022 (that can be in a separate IC package 1002(6)), one or more output devices 1024 (that can be in a separate IC package 1002(7)), one or more network interface devices 1026 (that can be in a separate IC package 1002(5)), and one or more display controllers 1028 (that can be in a separate IC package 1002(2)), as examples. Each of the memory system 1020, the one or more input devices 1022, the one or more output devices 1024, the one or more network interface devices 1026, and the one or more display controllers 1028 can be provided in the same or different IC packages 1002(5). The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display controller(s) 1028 sends information to the display(s) 1032 to be displayed via one or more video processors 1034, which process the information to be displayed into a format suitable for the display(s) 1032. The display controller(s) 1028 and video processor(s) 1034 can be included as ICs in the same or different IC packages 1002(5), and in the same or different IC package 1002(1) containing the CPU 1008, as an example. The display(s) 1032 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An integrated circuit (IC) package, comprising:
a package substrate;
an interposer substrate extending in a first direction, the interposer substrate comprising:
   a first metal layer comprising one or more first metal interconnects; and
   at least one metal post coupled to a first metal interconnect of the one or more first metal interconnects in the interposer substrate; and
a first die coupled to the package substrate, the first die disposed between the package substrate and the interposer substrate, the at least one metal post adjacent to the first die and thermally coupled to the first die.

2. The IC package of clause 1, wherein:
the first die comprises a back side, wherein the at least one metal post is adjacent to and thermally coupled to the back side.

3. The IC package of clause 2, further comprising:
a thermal interface material on the back side, wherein the at least one metal post is thermally coupled to the thermal interface material.

4. The IC package of clauses 1-2, wherein the one or more first metal interconnects comprise a first metal plate.

5 The IC package of clauses 1-4, wherein the interposer substrate further comprises:
a second metal layer comprising one or more second metal interconnects; and
an insulating layer disposed between the first metal layer and the second metal layer;
the insulating layer comprising one or more thermal vias each coupling a second metal interconnect of the one or more second metal interconnects to the first metal interconnect of the one or more first metal interconnects.

6. The IC package of clauses 3-5, wherein the at least one metal post contacts the thermal interface material.

7. The IC package of clauses 2-6, wherein the at least one metal post contacts the back side of the first die.

8 The IC package of clauses 1-7, wherein the interposer substrate further comprises at least one via electrically coupling a second die to the package substrate through the vertical interconnects.

9. The IC package of clauses 1-8, wherein the package substrate further comprises external interconnects disposed on a land side of the package substrate.

10. The IC package of clauses 1-8, wherein the first die further comprises an active side electrically coupled to the package substrate.

11. The IC package of clauses 5-10, wherein the one or more first metal interconnects comprise a first metal plate and the one or more second metal interconnects comprise a second metal plate.

12. The IC package of clauses 1-11, wherein the at least one metal post has a length between 30 micrometers (μm) and 100 μm, inclusively.

13. The IC package of clauses 1-11, wherein the at least one metal post comprises a plurality of metal posts, wherein a pitch between each neighboring metal post of the plurality of metal posts is between 100 micrometers (μm) and 200 μm, inclusively.

14. The IC package of clauses 1-11, wherein the at least one metal post comprises a plurality of metal posts, wherein an area defined by the plurality of metal posts is at least equal to an area of a back side of the first die.

15. The IC package of clauses 1-11, wherein the at least one metal post comprises a plurality of metal posts, wherein the IC package further comprises a molding compound disposed between the plurality of metal posts.

16. A method of fabricating an IC package, comprising:
providing a package substrate;
providing an interposer substrate extending in a first direction, the interposer substrate comprising a first metal layer, the first metal layer comprising one or more first metal interconnects;
providing at least one metal post coupled to a first metal interconnect of the one or more first metal interconnects;
disposing a first die between the package substrate and the interposer substrate coupling the first die to the package substrate; and
thermally coupling the first die to the at least one metal post adjacent to the first die.

17. The method of clause 16, wherein providing the interposer substrate further comprises:
forming one or more second metal interconnects in a second metal layer;
forming an insulating layer between the first metal layer and the second metal layer; and
forming thermal vias in the insulating layer coupling the one or more second metal interconnects to the one or more first metal interconnects.

18. The method of clauses 16-17, wherein thermally coupling the first die to the at least one metal post adjacent to the first die further comprises:
applying a thermal interface material on a back side of the first die.

19. The method of clause 18, wherein coupling the first die to the package substrate and disposed between the package substrate and the interposer substrate further comprises:
positioning the at least one metal post to contact the thermal interface material.

20. The method of clauses 18-19, wherein coupling the first die to the package substrate and disposed between the package substrate and the interposer substrate further comprises:
positioning the at least one metal post to contact the back side of the first die.

21. The method of clauses 16-20, wherein providing the interposer substrate further comprises:
forming a plurality of vertical interconnects between the interposer substrate and the package substrate, electrically coupling a second die to the package substrate through the plurality of vertical interconnects.

What is claimed is:

1. An integrated circuit (IC) package, comprising:
a package substrate;
an interposer substrate extending in a first direction, the interposer substrate comprising:
a first metal layer comprising one or more first metal interconnects; and
at least one metal post coupled to a first metal interconnect of the one or more first metal interconnects in the interposer substrate; and
a first die coupled to the package substrate, the first die disposed between the package substrate and the interposer substrate, the at least one metal post adjacent to the first die and thermally coupled to the first die.

2. The IC package of claim 1, wherein:
the first die comprises a back side, wherein the at least one metal post is adjacent to and thermally coupled to the back side.

3. The IC package of claim 2, further comprising:
a thermal interface material on the back side, wherein the at least one metal post is thermally coupled to the thermal interface material.

4. The IC package of claim 1, wherein the one or more first metal interconnects comprise a first metal plate.

5. The IC package of claim 1, wherein the interposer substrate further comprises:
a second metal layer comprising one or more second metal interconnects; and
an insulating layer disposed between the first metal layer and the second metal layer;
the insulating layer comprising one or more thermal vias each coupling a second metal interconnect of the one or more second metal interconnects to the first metal interconnect of the one or more first metal interconnects.

6. The IC package of claim 3, wherein the at least one metal post contacts the thermal interface material.

7. The IC package of claim 2, wherein the at least one metal post contacts the back side of the first die.

8. The IC package of claim 1, wherein the interposer substrate further comprises at least one via electrically coupling a second die to the package substrate through the vertical interconnects.

9. The IC package of claim 1, wherein the package substrate further comprises external interconnects disposed on a land side of the package substrate.

10. The IC package of claim 1, wherein the first die further comprises an active side electrically coupled to the package substrate.

11. The IC package of claim 5, wherein the one or more first metal interconnects comprise a first metal plate and the one or more second metal interconnects comprise a second metal plate.

12. The IC package of claim 1, wherein the at least one metal post has a length between 30 micrometers (μm) and 100 μm, inclusively.

13. The IC package of claim 1, wherein the at least one metal post comprises a plurality of metal posts, wherein a pitch between each neighboring metal post of the plurality of metal posts is between 100 micrometers (μm) and 200 μm, inclusively.

14. The IC package of claim 1, wherein the at least one metal post comprises a plurality of metal posts, wherein an area defined by the plurality of metal posts is at least equal to an area of a back side of the first die.

15. The IC package of claim 1, wherein the at least one metal post comprises a plurality of metal posts, wherein the IC package further comprises a molding compound disposed between the plurality of metal posts.

16. A method of fabricating an IC package, comprising:
providing a package substrate;
providing an interposer substrate extending in a first direction, the interposer substrate comprising a first metal layer, the first metal layer comprising one or more first metal interconnects;
providing at least one metal post coupled to a first metal interconnect of the one or more first metal interconnects;
disposing a first die between the package substrate and the interposer substrate coupling the first die to the package substrate; and
thermally coupling the first die to the at least one metal post adjacent to the first die.

17. The method of claim 16, wherein providing the interposer substrate further comprises:
forming one or more second metal interconnects in a second metal layer;
forming an insulating layer between the first metal layer and the second metal layer; and
forming thermal vias in the insulating layer coupling the one or more second metal interconnects to the one or more first metal interconnects.

18. The method of claim 16, wherein thermally coupling the first die to the at least one metal post adjacent to the first die further comprises applying a thermal interface material on a back side of the first die.

19. The method of claim 18, wherein coupling the first die to the package substrate and disposed between the package substrate and the interposer substrate further comprises:
positioning the at least one metal post to contact the thermal interface material.

20. The method of claim 18, wherein coupling the first die to the package substrate and disposed between the package substrate and the interposer substrate further comprises:
positioning the at least one metal post to contact the back side of the first die.

21. The method of claim 16, wherein providing the interposer substrate further comprises:
forming a plurality of vertical interconnects between the interposer substrate and the package substrate, electrically coupling a second die to the package substrate through the plurality of vertical interconnects.
